(19) United States
(12) Patent Application Publication
(10) Pub. No.: US 2010/0241471 A1
(43) Pub. Date: Sep. 23, 2010

(54) INTEGRATION SYSTEM SUPPORTING DIMENSIONED MODELING SYSTEM

(75) Inventors: Paul Nylander, Laguna Niguel, CA (US); Gerry Rey, Buena Park, CA (US); Sanford Damasco, Irvine, CA (US); Ryan Trinidad, Corona, CA (US); Paul Buckley, Oak Park, CA (US); Paolo Hilario, Walnut, CA (US)

Correspondence Address: KNOBBE MARTENS OLSON & BEAR LLP, 2040 MAIN STREET, FOURTEENTH FLOOR, IRVINE, CA, 92614, US

(73) Assignee: SCENARIO DESIGN, LLC, Anaheim, CA (US)

(21) Appl. No.: 12/407,585

(22) Filed: Mar. 19, 2009

(51) Int. Cl. G06Q 10/00; G06F 19/00; G06Q 50/00

(52) U.S. Cl. 705/7; 700/107

(57) ABSTRACT

The disclosed inventions and embodiments relate to the propagation of information among workflow applications used by a design project such as a construction design project and the creation and use of dimensioned and animated models for such projects. The workflow applications may be extended to enable participation in the information sharing or the system may provide functionality external to the tools that facilitates the participation of the tools. Information from various sources, including the workflow applications and third party sources, can be represented and modeled in an animation system. Sometimes the propagation is enabled in part by a store of information that also enabled reuse and reporting. Information used and generated by the various workflow applications is kept consistent among the different workflow applications and among the different representations of that information.

### CROSS-REFERENCE TO RELATED APPLICATIONS

This application is being filed concurrently with a U.S. patent application titled INTEGRATION SYSTEM SUPPORTING DIMENSIONED MODELING SYSTEM. Both applications have substantially identical disclosures.

### BACKGROUND

1. Technical Field

The present disclosure relates generally to computer-aided design and, more specifically, to a system for the interoperability of multiple tools to create, visualize and modify designs for construction and design projects.

2. Description of the Related Art

Designers of physical structures model actual entities that have yet to be implemented or constructed. They do so by manipulating and creating representations of those entities at different levels of abstraction, ranging from abstract models to basic objects that faithfully represent all of the relevant details of actual parts that can be sourced, manufactured, or otherwise obtained. A design should capture the requirements for the entity being designed—including the requirement that it be possible to implement the entity.

A model is a representation of an entity or product that need not capture all the details of the implemented product and which may vary in one or more ways from the actual implementation that the model represents. The various elements of a design, such as a theme park or building complex, may be modeled separately and these models may be integrated into a master-model. Models may be categorized as “organic” or “regular”. An organic model typically represents something living or natural, having limited regular structure (examples include mountain and rock formations, bodies of water, clouds, lighting, and motion). A regular model typically represents something artificial, especially those used in construction, having a generally regular or repetitive structure.

While models are high-level abstractions often meant to represent the look and feel of the product being designed, designers also make sure that the product can be implemented. To this end, designers work with objects. Like models, objects are abstractions, but objects represent more granular components of a design and do so with more detail and a greater focus on fidelity to dimensions and actual properties. An object may comprise an assembly of other objects. Typically, an object is ultimately comprised of one or more basic objects, each of which represent an actual part or item that can be sourced (e.g., 2×4's, girders, and screws) or produced (e.g., custom made components). An object may be susceptible to different views. For example, a structural or internal view allows a designer to review or manipulate the object's composition and constituent sub-objects: the materials from which it is made and its internal framework. An organic or external view of an object presents some of that object's outward facing properties such as its dimensions, its shape, and its color.

Through the design process (the development of models, the decomposition of those models into high-level objects, and the design of those high-level objects out of basic objects), a design for an actual implementation of a product is produced. This design includes not just the models and objects, but also metadata about the design project, such as assembly instructions for creating higher level objects out of assemblies of basic objects.

Clients, which may include both third-party customers of a design firm and in-house users of an internal design team, often have requirements not just for the finished product itself, but also for the design project and for the implementation or construction of the product. For example, a client may want a design for a building with particular features, and they may want that design in two months for $100,000. They may also require that the design be such that the building can be built in 10 months and that producing the built building cost no more than $5,000,000.

After the initial requirements are determined, an early step in a design project is often the creation of the master-model. Master-models are often created by hand, but computer programs such as modeling and animation tools can be used. Often, the client or someone with similar authority must approve the master-model before further work is done. Next, the designers may further refine or decompose the master-model into submodels. The master-model and any submodels may be predominantly organic or regular, as described above. Although designers can hand-create a model that is both organic and regular, such a model can be difficult to create and manipulate using computer-aided design tools. For example, existing design tools tend to emphasize support for either organic models (e.g., 3DS Max™, Autodesk Maya™, or Softimage/XSI™) or regular models (e.g., SolidWorks™, ProEngineer™, Revit™, or ArchiCAD™), but not both. As a result, it is often difficult to integrate models of the organic aspects of the product with models of the regular aspects of the product. It is particularly difficult to do so in a way that allows the client to experience the master-model and see that their requirements are understood and addressed. It is similarly difficult to do so in a way that lets other members of the design team fully explore a model, especially one containing both regular and organic aspects.

When designers create objects they may do so manually, but very often they use computer programs. SolidWorks™, ProEngineer™, Catia™, and Inventor™ are examples of engineering or CAD tools used by designers to manipulate objects. Some of these tools are focused on structural/internal views of the objects and, for example, allow designers to perform finite element analyses or modify the subjects from which an object is assembled. Others are used primarily for their organic/external views, with which designers manipulate the colors or dimensions of an object. Given that designers and design teams often use multiple object manipulation tools, one problem they face is ensuring that the changes propagate across all of them. For example, it is not desirable for the dimensions of an object to be changed and for that change not to be apparent to the designer of the internal structure of that object. Another problem is in ensuring consistency: it is not desirable for a designer manipulating an organic view to give an object dimensions that can not be implemented structurally or that would consume a prohibitive amount of resources when implemented. Unfortunately, if the structural limitations are only apparent when using a structural view tool then a user of an organic view tool is at increased risk of being unaware of them, and a user wishing to assess the impact of a change on the overall design and the interaction of that change with the project's metadata faces a daunting challenge.

The quality of the connection between objects and models is also a source of frustration with current design tools. Models are often the basis for the design of objects, but objects and models are not tightly coupled. One problem is that the correlation between objects and models is generally ad-hoc and there is a degree of risk that the various objects, when assembled, will not comprise a macro-object that is faithful to the vision represented in the master-model. Also, designers creating objects may be guided by information in the model, but the particulars of what aspect of the model informed what aspect of an object is usually not recorded anywhere. There is little tool support for this and if designers want to track which objects are associated with particular aspects of a model, they would find it difficult. Similarly, making changes to a model after work on the objects has commenced may require discarding and redoing substantial amounts of object design work and trying to recapture a mental context that the designers are no longer in. Another problem is that the relationship is unidirectional: models do not reflect the ongoing design of the objects so that if a design change is made and incorporated in objects, the change will typically not be reflected in a model without manually updating the model.

Design projects often include schedule and budget data. This information, like the previously mentioned assembly instructions, is an example of project metadata. To some extent, project management tools allow for a design project to be managed according to a schedule and budget. However, it is difficult to manage or even represent the relationships among the objects, models, and metadata. For example, it is difficult to visualize and monitor the time and cost of designing individual objects relative to the overall design project. It is also difficult to assess the impact (including to the budget, the schedule, the structural integrity, and the organic appearance) of replacing one object with an alternative.

Some of the outputs of a design project are inputs for a construction or implementation project. So, for example, when referring to the actual parts that are used to build the product, design projects may use a standard notation such as the MasterFormat™ specification published by the Construction Specifications Institute and Construction Specifications Canada. It would be beneficial if designers, when designing, could account for implementation costs and schedules as well as design costs and schedules. It would also be helpful to capture and represent the connection between the design and the implementation so that, for example, designers and clients understood the impact a design choice had on the design cost and budget, on the implementation cost and budget, and on the experience (look and feel) of the implemented design.

Although a master-model is generally agreed upon in the beginning of the design process and serves as the basis for future design work, as the design proceeds it is difficult to get a holistic sense of the design. In part this is because the objects may be represented in blueprints, specification sheets, or in CAD and architecture tools, all of which may reflect many, but not necessarily all, of the decisions about the internal structural properties and external organic properties of the objects but none of which tend to convey how an object affects the experience of the implementation. Similarly, as mentioned above, significant design decisions may only be reflected in the (distributed) design of the objects or in sub-models but not in the master-model. Someone viewing the representations of the objects, the sub-models, and the master-model may find it extremely challenging to determine what the experience of an implementation of the design, at that point in time, would actually be. It would also be very difficult to determine if the design accurately reflected the current requirements or even if the objects, when assembled, would provide the experience represented in the master-model. Similar problems exist with respect to project metadata: as the properties of objects are defined, it is possible to associate costs and implementation times with them. But it is difficult to aggregate this low-level data to ascertain, for example, that particular user-experience features of a model are expensive or have an extended delivery time.

It is also beneficial for designers to be able to reuse work. For example, the same or substantially similar product might be implemented in multiple locations. Similarly, the same or substantially similar parts (represented by correspondingly similar objects) might be used in multiple designs. Reuse of objects or even complete designs can be achieved currently, subject to inconvenient restrictions. Design reuse is difficult if different design tools are used. Tweaking, as opposed to exact reuse, is particularly difficult. For example, supply, cost, local regulations, or regional climate conditions may necessitate use of a particular material or a particular vendor in a design that is otherwise unchanged. Current systems do not readily accommodate such tweaking. It would be useful if changes in objects, including basic objects, could be made once and propagated throughout the design so that they are reflected in all the tools and so that their effects on the overall design can be efficiently accommodated.

### SUMMARY OF THE DISCLOSURE

Various inventions and embodiments of those inventions are disclosed. Aspects of multiple inventions may be represented in combination by single embodiments, while other embodiments may represent individual inventions. The various embodiments generally address the problems and issues identified above and provide other benefits over the current art. The disclosed inventions and embodiments can also be used to implement the prior art described above.

Many of the embodiments disclosed relate to the propagation of information among workflow applications used by a design project. Sources of the information include third parties, traditional and electronic documents, the workflow applications being used, and previous projects. The information includes information about the target product being designed and about the components that comprise the product. The information also includes information about implementing the design, including information on procuring the components and combining them to create the product. The workflow applications include design, architecture, engineering, reporting, and project management tools. In some embodiments, at least one of the workflow applications is an animation or simulation application. Workflow applications may be extended to enable participation in the information sharing, or functionality external to them may facilitate their participation.

Many of the disclosed embodiments also include or interact with a store of information about a design project such that the store of information enables reuse and reporting. A preferred embodiment is a system that includes a data repository containing information about current and previous design projects and an integration engine that manages and maintains the information in such a way that it is internally consistent and accessible by systems that wish to query the repository, thereby enabling various workflow applications to use the data. In some embodiments, the data repository maintains the consistency of the information at a data integrity level, and in some embodiments it also provides functionality to help ensure that the information in the repository is consistent with the overall goals of the design project.

### BRIEF DESCRIPTION OF THE DRAWINGS

FIG. 1 illustrates a high-level view of an embodiment that connects different workflow applications and third party data sources to a master database and includes an animated master-model workflow application that can render animated simulations of the information in the database.

FIG. 2 shows how such an animated master-model workflow application might make use of the information available to it to render dimensioned information and metadata.

FIG. 3 shows how a master-model workflow application can display information reflecting the current state of the design, including detailed information not typically associated with a model.

FIG. 4 shows an embodiment that can manage information and metadata about the design and how a master-model workflow application can use that information according to an embodiment of this invention to display information about the anticipated implementation and the implementation process.

FIG. 5 depicts a modeling process and illustrates how an embodiment of the system allows a master-model to display information from both organic and regular modeling workflow applications.

FIG. 6 shows an embodiment that facilitates coordinated use of different engineering and design workflow applications, provides those workflow applications with a portion of the design reflecting a scene in a master-model workflow application as a starting point for further refinement, and propagates the results of using those workflow applications to other workflow applications, including the master-model workflow application.

FIG. 7 illustrates how an embodiment supports the use of third party data and data not associated with workflow applications, the reuse of work from earlier projects, and the generation of reports.

FIG. 8 presents an embodiment of the master database.

FIG. 9 is an illustration of different adapter embodiments, including connectors and plug-ins.

FIG. 10 illustrates an additional embodiment of a design process and system where live models provide access to a broad range of design information.

### DETAILED DESCRIPTION OF PREFERRED EMBODIMENTS

Various inventions and embodiments of those inventions are disclosed. Aspects of multiple inventions may be represented in combination by single embodiments, while other embodiments may represent individual inventions.

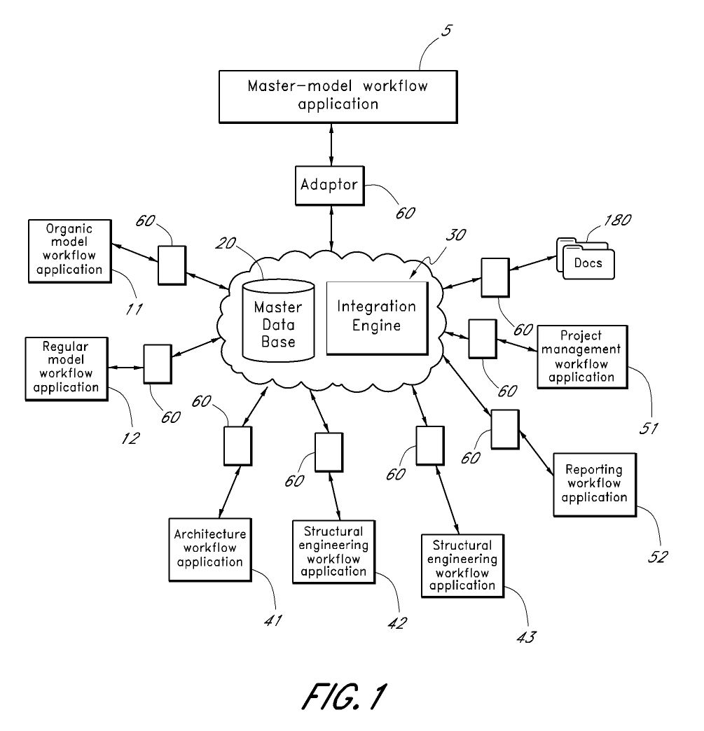

The disclosed embodiments include systems that support a design process, as illustrated in FIG. 1. Throughout this description of FIG. 1 and subsequent figures, certain terminology will be used and embodiment-specific details such as workflow application types, data types, algorithms, rules, and conventions will be referenced. This is done to illustrate particular embodiments, and not to limit the scope of any of the disclosed inventions. Thus, nothing in the drawings or this detailed description should be construed to imply that any particular feature, component, or aspect of the system or the associated design process is a requirement of any claim.

### Using Embodiments of the Inventions in Design Projects

A goal of a design project is to deliver plans and specifications sufficient to enable creation of an actual implementation. A project will typically, but not necessarily, have at least one internal or external client, whose approval is necessary before the project is considered complete. That client may have a general idea for a product, such as a building, theme park, movie set, or exhibit display.

Design teams not using what is disclosed in this application would typically behave as follows. The designers would discuss that idea with the client and refine it into a model: a relatively abstract, undimensioned representation of the idea. After the client and designers agree on the model, the designers begin to design objects. For such a design team, objects and models are distinct: for example, objects are dimensioned, can be analyzed using engineering principles, and can ultimately be described to a level of detail that corresponds to specifying how they are to be made or assembled. Models, in contrast, represent an understanding of the overall goals of the design project but do not represent how the delivered product will be implemented. While these designers may look to the model when designing the objects, the model is generally changed only in response to changes in the goals of the project: it does not reflect design decisions about the objects. Indeed, the model, which is the only user-friendly representation of the design during much of the design project, might not even be updated to reflect changes to high level requirements if such changes are communicated directly to object designers. The designers themselves operate under a myriad of restrictions discussed above.

In contrast, a design team taking advantage of what is disclosed in this application can realize benefits that will positively affect them, their clients, and third parties.

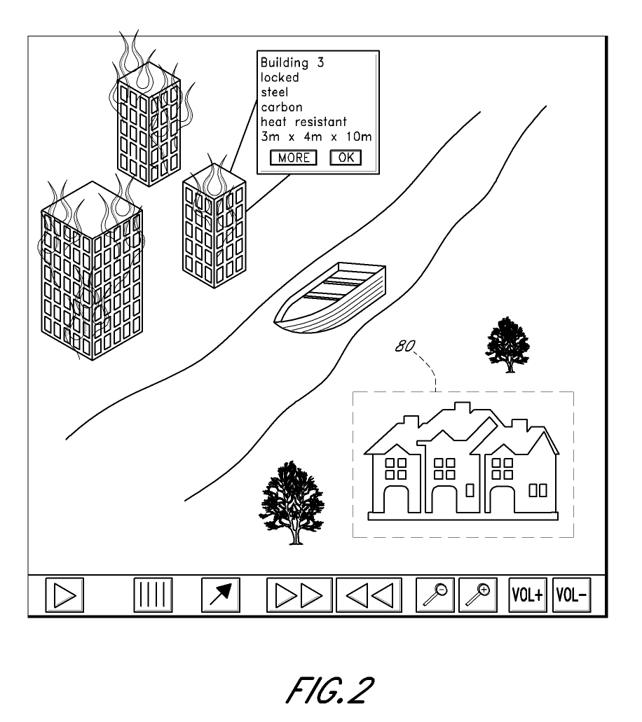

For example, after discussing the initial requirements with the client, the designers might create a model in a master-model workflow application (5). The master-model workflow application might display a fully animated and interactive representation of the model, allowing clients, designers, and others to zoom in and out, to pan, to visualize the model as time goes by or as money is spent, and to fully experience the planned deliverable. See FIG. 2. In an appropriate master-model workflow application (5), the master model may be dimensioned from the beginning of the design project.

In further contrast to the previous design team, a design team advantageously using what is disclosed need not maintain distinct models and objects. Instead, in some embodiments the information about the design project is maintained in a master database (20). From there it is made available to the full panoply of design workflow applications, including those traditionally used to design models and those traditionally used to design objects. Rather than distributing design decisions and design project information among a multitude of models and objects, such an embodiment features a central source of design information.

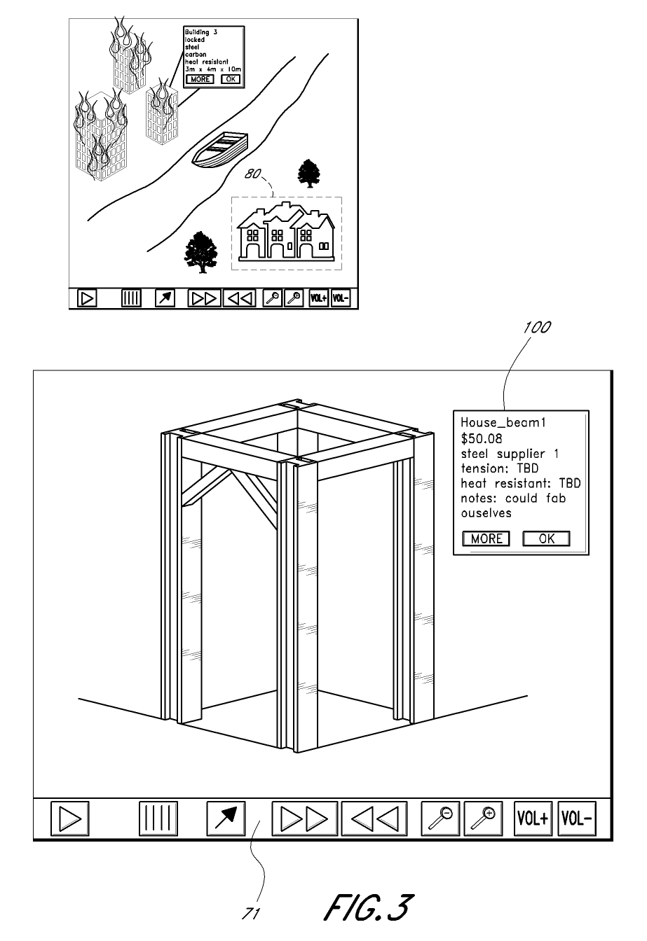

Thus, when the design of objects begins, the designers can select portions of the design, for example by selecting a scene from a display in a master-model workflow application (See 80 in FIG. 3), and start designing the objects for that portion of the design. The various workflow applications used to design those objects will have access to extant design information. For example, color, relative dimensions, and basic physical properties may have been decided by the designers when modeling. Using what is disclosed, these previously made decisions, including any dimensioned data, are available to the object designers.

Moreover, as the objects are further designed and refined, the master-model workflow application displays an updated model which incorporates the refinements and design decisions. The master-model workflow application still provides the original functionality (e.g., animation, zooming, panning) but now what is being experienced may faithfully represent detailed design decisions and not merely a modeler's abstract conception. In appropriately configured master-model workflow applications, users can experience or see the actual detailed design information, traditionally unavailable in a model.

If the design system includes information about the costs and implementation details of the objects, as in some embodiments, then the master-model workflow application may also present that information. This allows, for example, designers and clients to experience, in animated fashion, the implementation of a product as time passes or money is spent.

An actual implementation is constructed in actual time from actual material, actual labor, and actual funding (or, if a virtual construction in an online universe such as Second Life™ is being designed, then time, materials, labor, and funding may be virtual and actual). The parts lists, blue prints, pricing material, assembly instructions, and all of the other information necessary to construct a completed design traditionally might be created using multiple tools based on information distributed across multiple systems or maintained by multiple people. Designers using what is disclosed are able to access all of that information, regardless of its original source, and generate the necessary outputs. Indeed, if the design has progressed to the point where the necessary information is available, then a client satisfied with the design as experienced in a master-model workflow application can immediately have appropriate information sent to manufacturing, procurement, and construction systems to begin constructing the actual product. Similarly, information from completed or ongoing implementation projects can be incorporated back into embodiments of what is disclosed, allowing designers and others to view reports such as spend versus budget and to determine elements of a design were and were not implemented.

### Workflow Applications

During a design project, workflow applications are used to perform tasks such as modeling, engineering, and management and reporting. Generally, a user of a workflow application will need to take into account work done in other workflow applications —work that traditionally is not readily accessible to the workflow application. Such external work is often communicated to the user verbally or in writing. The user then reenters the information into their workflow application or otherwise accounts for it as they perform their design task. This is an error-prone and laborious process.

The modeling system depicted in FIG. 1 includes an integration system that integrates a variety of workflow applications. These workflow applications preferably include modeling workflow applications (including a master-model workflow application (5), organic-model workflow applications (11), and regular-model workflow applications (12)), engineering workflow applications (including architecture workflow applications (41) and structural-engineering workflow applications (42)), and management workflow applications (including project management workflow applications (51) and reporting workflow applications (52)). Some workflow applications may be extensible, allowing for the provision of functionality beyond that provided natively. Such functionality may be provided by an adapter (60).

Embodiments of the various workflow applications may provide users with the ability to view, update, manipulate, and otherwise modify designs in ways not described. Also, a workflow application may natively or by an adapter (60) provide a function substantially similar to that provided by a different workflow application. Preferred embodiments are configured with appropriate permissioning systems such that a user can be denied access to a particular function across the entire embodiment, regardless of which application she uses to try to access that function.

The workflow applications will typically run on one or more general purpose computers or processors or their functional equivalents, such as virtualized hardware. In more preferred embodiments, the workflow applications run on computer systems running operating systems in the Microsoft Windows™, Apple MacOS™, or UNIX™ families. A workflow application may, for example, run on a computing system having multiple processors or processor cores, multiple terabytes of persistent storage (e.g., hard disk drive storage), and multiple gigabytes of solid-state RAM. A practitioner will appreciate that the evolution of hardware and software and the requirements of a specific project will all influence the need for hardware in any particular embodiment. The different workflow applications may run on common or distinct computing platforms.

In some embodiments, and as further illustrated in later figures, the modeling workflow applications include a master-model workflow application (5) which generates simulations or animations that present viewers with the experience of the designers' representation of the actual implementation. The master-model workflow application (5) may include animation software such as 3D Studio Max (3DS Max)™ or Autodesk Maya™. The master-model workflow application (5) preferably includes animation software that is extensible, such as 3DS Max™.

Generally, engineering workflow applications include workflow applications that allow users to represent the actual components of the implementation being designed and those things necessary to its implementation. For example, where a design project is targeted at an actual implementation which will be composed of actual material assembled by actual labor, engineering includes the tasks of specifying the actual materials to be used based on properties of those materials (for example, cost, availability, physical and other inherent properties, and customer preference), determining how to assemble these actual materials into any actual assemblies necessary for the actual implementation, determining the configuration of those assemblies relative to one another, and defining how and when the assemblies should be constructed so the actual implementation can be built. Engineering tasks supported by engineering workflow applications include, for example, structural and mechanical analysis, component selection and design, and architecture.

Management workflow applications support non-engineering and non-modeling tasks. Examples of such tasks include establishing baseline time and cost budgets for a design project and tracking the project to those baselines, similarly managing the cost and schedule of the construction or implementation project to deliver the actual implementation; recording and managing notes about clients, suppliers, and other parties and entities involved in the design project; and generating reports and other outputs such as plans and specifications, budgets, and schedules.

### FIG. 1

FIG. 1 illustrates an embodiment wherein a master-model workflow application (5) and other workflow applications (including other modeling workflow applications (11 and 12), engineering workflow applications (41, 42, and 43), and management workflow applications (51 and 52)) interface with a master database (20) and an integration engine (30) via adapters (60).

The master database (20) of FIG. 1 may be implemented by any computing system running software capable of supporting a queryable data repository and including computer storage sufficient to store the data associated with the design project and computer processing sufficient to update and query the repository in a timely fashion. In some embodiments, the master database (20) includes multiple distinct sub-databases. For example, the master database (20) may include the native datastores associated with the workflow applications.

In preferred embodiments, the master database (20) also provides functionality for managing documents (180). Documents (180) may be computer representations of information, such as the computer files generated by a computer application or the results of importing a paper file into a computing system. Managed documents include those documents associated with workflow applications and those that are not associated with any particular workflow application but are relevant to the design project (e.g., in some embodiments these include client requirement documents, contracts, vendor catalogues, and parts lists). Document management functionality includes file storage, revision control, and versioning. By incorporating such functionality, the master database (20) becomes more flexible and inclusive. For example, such functionality is not necessary if data and metadata about a project is stored in a data repository in the master database (20), where it can be accessed by adapters (60) that provide workflow applications with design project information that might not otherwise be available to those workflow applications. But retaining and managing documents is particularly advantageous in embodiments that interact with workflow applications with limited or no extensibility features and when it may be efficient or otherwise beneficial to directly access a document.

Documents (180) from which data cannot be readily extracted (for example, some PDF or image documents) or which may be significant more as integrated documents and less as containers of information (for example, contracts or notices) may be stored primarily using the document management functionality. Documents whose primary purpose is to structure project data for use by particular workflow applications would more typically be generated as needed from the master database (20). Nonetheless, in some embodiments, the document management functionality of the master database (20) manages some documents, including those generated by the workflow applications. Such a configuration readily supports tracking revisions to those documents and the provision of roll-back and versioning of the overall design, although such functionality can also be provided in other embodiments. In some embodiments, after information is retrieved from documents (180), the original documents are not managed by the embodiment but appropriately structured documents can be recreated or generated based on information about the project and the document format.

The master database (20) may be implemented using modern relational database systems in conjunction with modern document management systems. An example of such a master database (20) comprises Microsoft SQL Server™ and the SolidWorks PDM Vault™ that is a component of SolidWorks PDMWorks™. One of the advantages of such an embodiment is the extensibility of relational databases and document management systems. Another is that PDM Vault is well integrated with the SolidWorks applications that are widely used in design projects. This integration reduces the burden born, in some embodiments, by adapters (60). Other embodiments using different means to provide document management functionality can be configured to be at least as functional. The master database (20) software may be run on computing hardware (or virtualized computing hardware) similar to that used by the workflow applications and disclosed above.

The integration engine (30) may be implemented by software modules associated with the master database (20), such as rules, triggers, or extensions to the underlying database system of a given embodiment. Other embodiments include systems that are independent of but in communication with the master database (20), such as rules engines or business automation engines. In one embodiment, the integration engine (30) comprises rules and triggers written in T-SQL and taking advantage of the programmability provided by Microsoft SQL Server™. Another example embodiment distributes the function of the integration engine (30) among the one or more adapters (60) so that the business logic for updating the master database (20) and ensuring its integrity is contained within each adapter. With this approach, an appropriate mechanism may be provided for updating affected adapters when the business logic changes.

In preferred embodiments, the integration engine (30), whether implemented by a separate system, by the master database (20), by the adapters (60), or by other means, is responsible for maintaining the integrity of the system, implementing business logic, and enabling the various adapters (60) to operate. Preferably, data necessary for the integration engine to function is stored in the master database (20). For example, the integration engine (30) may be responsible for resolving issues around simultaneous or concurrent access to documents (180) and information managed by the master database (20). It may, for example, flag documents or data that are currently being manipulated in a workflow application so that other workflow applications do not attempt to modify that data. In other situations it may compare modifications to documents and data made by different workflow applications and determine if the cumulative set of modifications can be retained or if potential incompatibilities need to be resolved. In some embodiments, the integration engine (30) may manipulate data and documents in ways that are appropriate for that embodiment, such as to enable the animation supported by an animated master-model workflow application (5) or to ensure that elements of the design are appropriately tagged and formatted so that they can be made accessible to the workflow applications.

Another example of a task performed in some embodiments by the integration engine (30) is permissioning and access logging. Permissioning ensures that only authorized users can perform particular activities; access logging is the process of recording what activities are performed by whom. The integration engine (30) may be configured, in some embodiments, to only allow authenticated users to read from or write to the master database (20) or particular items managed by it. In some embodiments, permissioning may be based on the particular computing systems on which instances of workflow applications are running, such that workflow applications running on a particular network segment, for example, will have particular access permissions. Embodiments may implement other permissioning schemes as well. Embodiments may implement access logging at various levels of granularity, including tracking the computing system on which an accessing workflow application is running; the user of that workflow application; the time and date of that access; and the extent of that access, including the data and documents modified or accessed. In other implementations, permissioning and access logging may be performed by a workflow application. In various embodiments the integration engine (30) performs other tasks necessary to implement the functionality described herein as well as additional tasks necessary for functionality that is not described but would be obvious to skilled computing and design artisans implementing embodiments of the present inventions.

As shown in FIG. 1, some embodiments feature adapters (60) that enable interoperability between workflow applications and a master database (20) or integration engine (30). Embodiments might also feature communication directly between two different workflow applications, perhaps also facilitated by adapters (60). The interoperability, which may be over any feasible communications mechanism, including the internet, WANs, and LANs, but preferably via a high-speed LAN, comprises reading from, querying, and possibly writing to the master database (20). This may be done through direct files access, SQL, and/or other interfaces and API's that are appropriate to the embodiment of the master database (20). Preferably, each adapter (60) has access to and complies with business rules that control the organization of the master database (20). An integration engine (30) may store these rules and ensure that they are complied with.

The additional functionality which adapters (60) may provide to target workflow applications, such as the master-model workflow application (5), include representing data not native to the target workflow application, querying the master database (20), allowing write access to the master database (20), and providing access to functionality or services external to the workflow application (such as permissioning).

FIG. 2

FIG. 2 illustrates a screen-shot from the master-model workflow application (5) of an embodiment where the master-model workflow application (5) is implemented using animation software such as 3DS Max™. The product being designed is a boat ride through a landscape of burning buildings. FIG. 2 depicts a screen-shot taken at a point in the design project when much of the high-level design (modeling) is complete and some of the objects have been designed in detail using various workflow applications. FIG. 2 shows that in some embodiments, a master-model workflow application (5) is capable of presenting a comprehensive survey animation of the design. In some of these embodiments, the data rendered by the animated master-model workflow application (5) is sourced from the master database (20) and may have been originally created or entered from any of the workflow applications or imported from documents and sources external to the design project (180)—e.g., documents which were not created by the system or by a member of the design team using a workflow application. The illustrated animated master-model workflow application (5) allows users to explore the design from different perspectives, and to zoom in and out on elements of the model. In other words, the screen-shot depicted in FIG. 2 represents a ‘still’ from an animation: an image from a particular perspective and zoom-level of an animation that might include the boat moving through the river, the water flowing, the buildings burning, and trees moving in a breeze. Preferably, an animated master-model workflow application (5) also allows users to set parameters such as time of day, time of year, stresses experienced by the implementation (such as the number of people in a building or the number of times a particular mechanism has been used) and weather conditions. Such an animated master-model workflow application (5) may then allow users to experience a design under the specified conditions. A set of these settings, perhaps including time-series data, can also be processed by some animated master-model workflow applications (5), allowing for predefined conditions to be simulated and for time-series data to be animated and thereby allowing users to navigate designs geographically and temporally. These sets of settings are preferably stored in the master database (20) but may be stored in other locations. In some embodiments a workflow application may be used which specifically allows users to generate and manage this scenario data, but it may also be entered in other ways, such as directly through the animated master-model workflow application (5).

FIG. 2 also shows an example of how a preferred embodiment might make use of the data available to it. Here, an informational pop-up (100) is displayed in response to a user selecting an item in the animation display. More generally, data available to workflow applications in various embodiments includes the information reflecting design decisions made during the design project; data about the design process, such as when an element in the model was designed or by whom; and metadata about the relationships among the different components of the design and about how the design might be implemented. If the design project has progressed beyond initial modeling, then the master database (20) might contain additional data about the elements, and that additional data can be displayed in preferred embodiments of the master-model workflow application (5). For example, the values or data underlying the visual representation might be presented, or the subcomponents from which the element is assembled might be listed. Properties that do not lend themselves to representation in the context of animation, such as cost, load-bearing capacity, or magnetic strength, might be displayed. In short, because some embodiments of the master-model workflow application (5) source data from a master database (20) which contains information from workflow applications and third party sources (180), these embodiments have an extensive and comprehensive set of simple and derived project data to draw from when rendering the model. In some embodiments, users can configure the types of data that are displayed and how it should be presented. Some embodiments allow workflow applications other than the master-model workflow application (5) to similarly display such information.

In some embodiments, users of the master-model workflow application (5) or other modeling workflow applications can select elements of the model and mark them as a “scene” (80). Preferably, the ability to do that is based on permissions and business rules which are maintained by the integration engine (30). Data in the master database (20) representing the elements so marked is flagged, and users of the appropriate workflow applications may be alerted that design work should progress on those scenes. Appropriate workflow applications are determined based on business logic and configurations of the particular embodiment. A person of ordinary skill in the art will be familiar with systems and methods for alerting users and workflow applications to changes in data and to the need for those users and workflow applications to take action.

Not illustrated is an alternative view of the data rendered in a master-model workflow application (5). Preferably animated, this “experiential view” need not allow for the broad geographic and temporal exploration of the model that the “survey view” of FIG. 2 allows. Instead, the design is rendered from the perspective of an individual or entity behaving as a user of the actual implementation. For example, for the previously described design for a boat ride, an experiential view rendered by an animated master-model workflow application (5) might allow viewers to have the perspective of a simulated user who may turn her head and body to experience seeing the model in all directions. But if the actual user would be confined to a boat travelling a preplanned course, the experiential view might not allow the simulated boat-rider (and thus the viewer) to see the tops of tall buildings or the elements behind the buildings if they would not be visible to an actual boat-rider. An animated master-model workflow application (5) may allow for varying degrees of constraint on the perspective and geographic access the simulated user of the experiential view has. Thus, such an application (5) may allow viewers to experience the boat ride from the perspective of relatively unconstrained staff-members who maintain the ride. If the design project is for a hotel lobby, the experiential view may allow users to experience the design from the perspective of a person who is unconstrained geographically but is confined to a wheelchair. Preferred embodiments allow any combination of geographic and perspective constraints to be experienced.

### FIG. 3

Another way that a master-model workflow application (5) may advantageously represent information about the design is illustrated in FIG. 3. A portion of a model may be selected, much as when a scene is selected (80). To the extent that appropriate data is available, a master-model workflow application (5) then renders not just a zoomed-in or magnified view of the selected elements, but also renders a more detailed view of the selected elements. The information in this detailed view need not have been created using a master-model workflow application (5), but could originate from one or more other sources. Such a display might include the components from which the selected elements are assembled. The business rules that may control scene selection need not control the selection that leads to detailed zooming. In a preferred embodiment with an animated master-model workflow application (5), this more detailed view may be animated as described above, including survey views, experiential views, and simulations. As with other views, pop-up windows (100) and other ways of presenting more detail are provided in preferred embodiments.

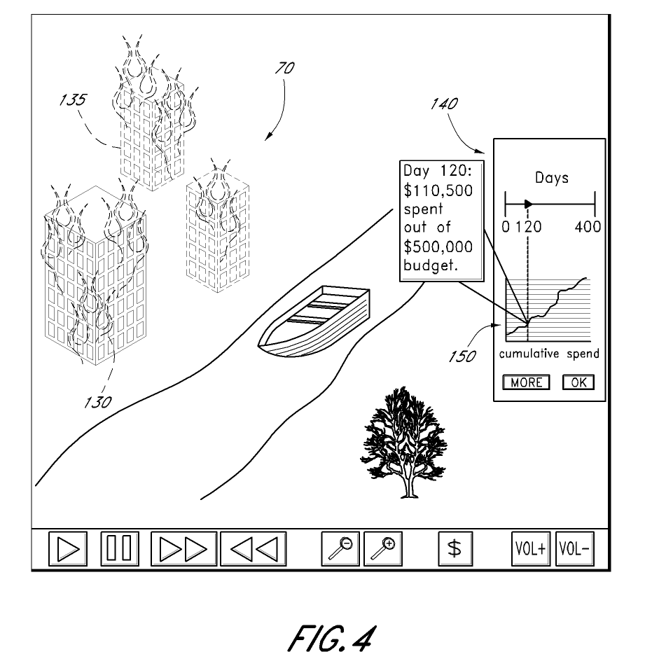

### FIG. 4

FIG. 4 illustrates how a preferred embodiment of the master-model workflow application (5) may display information not just about the design but also about the delivery or completion of the actual implementation. FIG. 4 again shows a screen shot of an animation produced by a preferred animated master-model workflow application (5). Although there are other ways to indicate and manipulate the passage of time in an animation, this figure shows a slider (140) with which a user can move the animation to different time periods and which shows, when the animation is proceeding, what time period is being displayed. What is being animated in this figure is the build-out or construction of the theme park ride presented above. Whereas FIG. 2 shows an embodiment animating the design at a given point in time, FIG. 4 shows an embodiment animating the construction or deployment of the current design. The illustrated scene shows that at the time period in question (day 120 of a 400 day schedule), some of the elements are scheduled to be complete, as indicated by the solid lines (130). Other elements, such as the flames, the boat, the trees, and some of the buildings, are not yet built, as indicated by the broken lines (135). Practitioners will appreciate that there any many ways to contrast complete and incomplete elements; for example, incomplete elements could be omitted completely, shown in a more translucent or less fully colored rendering, or outlined in a particular style.

Preferably, the animation and simulation functionality described in the discussion of FIG. 2 is also available when the master-model workflow application (5) is displaying views of the construction or implementation project as in FIG. 4. Thus, users may be able to experience the build-out of the actual implementation from various perspectives and at various levels of detail. FIG. 4 also illustrates another example of how data, including dimensioned data that is not traditionally represented in a model, can be displayed in some embodiments. In the illustrated implementation, a bar graph (150) charting the cumulative amount of money spent building the product moves in synch with the time of the build-out animation. In unanimated embodiments, the bar graph may correspond to the point of time being displayed in the master-model workflow application (5). Such representations can be implemented as appropriate for particular views, zoom levels, and perspectives. By way of illustration, if a master-model workflow application is displaying a detailed view, the cost shown may be only that of the elements shown or selected.

The master-model workflow application (5) may obtain data from the master database (20), which may have access to it because another workflow application or a third party (180) provided it. In other embodiments, the master-model workflow application (5) may have native functionality for calculating or deriving data or, in some embodiments, an adapter (60) or another workflow application may provide the functionality.

Embodiments of a master-model workflow application (5) are not limited to displaying views that represent what a user might typically see in a traditional design model (e.g., the visual appearance of the elements). Preferred implementations use data from the master database (20) and native functionality or functionality provided by an adapter (60) to allow for the display of simple data as well as data derived from simple data in conjunction with business rules, simulation data, and other properties of the elements in the model. For example, a master-model workflow application (5) can be configurable to display the temperature of the elements in particular conditions (valuable when temperature may affect some of the elements or the experience of users touching those elements) and the sounds that the various elements might emit when under stress or in use. Sound might be represented by actually emitting sounds if the embodiment supports that, but may be represented in other ways: for example, by color coding or otherwise visually flagging elements that are the source of sounds at particular pitches and decibel levels. In preferred embodiments, the master-model workflow application (5) can be configured to use this type of visual flagging as a proxy for any value that can be calculated from data available to it. As another example, an animation may use visual cues to show the wear-and-tear on the elements of the modeled structure as the number of users increases.

Similarly, some embodiments support animation based on other value-types stored in the master database (20). This functionality may be used to render a build-out animation largely as in FIG. 4 but based on the expenditure of money or consumption of construction resources instead of the passage of time. The ability to render this a broad range of data in a useful manner is a great advantage of combining an animated master-model workflow application (5) with a master database (20) that provides access to data normally isolated in different workflow applications and third party documents (180)

While the above descriptions and figures often refer to a master-model workflow application (5) providing functionality, some embodiments provide similar functionality in other workflow applications, using adapters (60) as necessary. For example, a user of an engineering workflow application who is determining what materials can support the loads necessary for a particular design may be able to bring up displays that show where else in the design similar loads are being directed. Or, such a user may be able to bring up a comprehensive load diagram that might help the user identify alternative design options. An engineering workflow application might also allow the user to view the objects that interact with the object being engineered. Such displays may be implemented using adapters (60) if they are not native to the workflow application. They are possible because in most embodiments, the engineering workflow application, like the master-model workflow application and other workflow applications, has the potential to access all of the information about the design project and to access metadata about how the various objects in the design relate to each other.

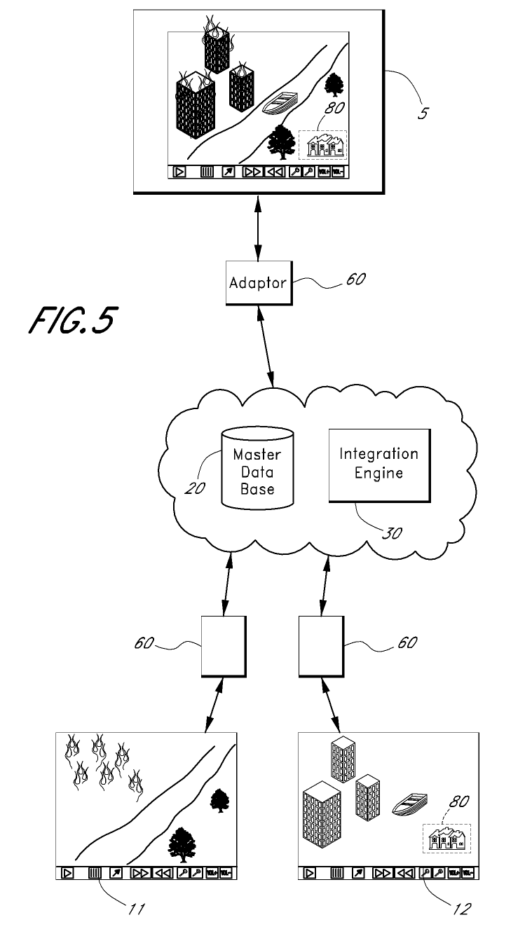

### FIG. 5

FIG. 5 illustrates an embodiment in which the master-model workflow application (5) has access to data that allows it to render models containing both regular and organic elements. A preferred master-model workflow application (5) is an animated computer graphics program such as 3DS MAX™, Autodesk Maya™, or Autodesk Softimage/XSI™. These and other similar programs are also well suited for developing organic models and may be embodiments of organic-model workflow applications (11). Current versions of these programs are less well suited for developing regular models. Examples of commercial applications that are better suited for use as regular-model workflow applications (12) include architecture tools such as DDS-CAD™, ArchiCAD™, and Autodesk Revit™ or CAD tools such as Dassault Systems SolidWorks™ and Catia™, Parametric ProEngineer™, and Autodesk Inventor™. Other workflow applications typically used in modeling include graphics programs such as Adobe Photoshop™ and Adobe Illustrator™.

In FIG. 5, an organic-model workflow application (11) is being used to model the organic elements of a design: hilly terrain, trees, a river, and flames. In some embodiments, additional modeling workflow applications might also be used. For example, the river and the flames might be modeled using a workflow application with functionality specific to modeling fluids and flows. FIG. 5 also shows a regular-model workflow application (12) being used to model the more regular elements of the model, such as the buildings and the boat.

In the illustrated embodiment, the modeling applications interact with the master database (20) and the integration engine (30) via adapters (60). It is preferred that each workflow application have one adapter (60) but that multiple instances of a workflow application each use a separate instance of that adapter. As was described above with respect to the master-model workflow application (5), connectivity between each of the modeling workflow applications (11 and 12) and the master database (20) and integration engine (30) is preferably via a high-speed LAN, but may be implemented using any technology that provides sufficient performance.

An embodiment providing this functionality allows a designer to use a modeling workflow application to draft an initial model. Using techniques similar to those described above with reference to selecting scenes, designers can refine elements of the initial model in other modeling workflow applications. Some embodiments also allow designers to model new elements not in the original draft. Because information about the elements is maintained in the master database (20), a designer using an organic-model workflow application (11) can rearrange and add additional detail to the trees, and those design decisions will be reflected in master database (20) and available to the master-model workflow application (5) and the regular-model workflow application (12), as well as any other workflow application. A designer can use the master-model workflow application (5) to reposition various elements without fear that design decisions made in a different workflow application will be lost or undone because the master-model workflow application (5) does not natively support making that type of design decision. Because information about the relationships among the elements is also maintained in the master database (20), embodiments applying business rules to the information in the master database (20) can alert designers when new design decisions conflict with earlier ones or require modifications to other elements.

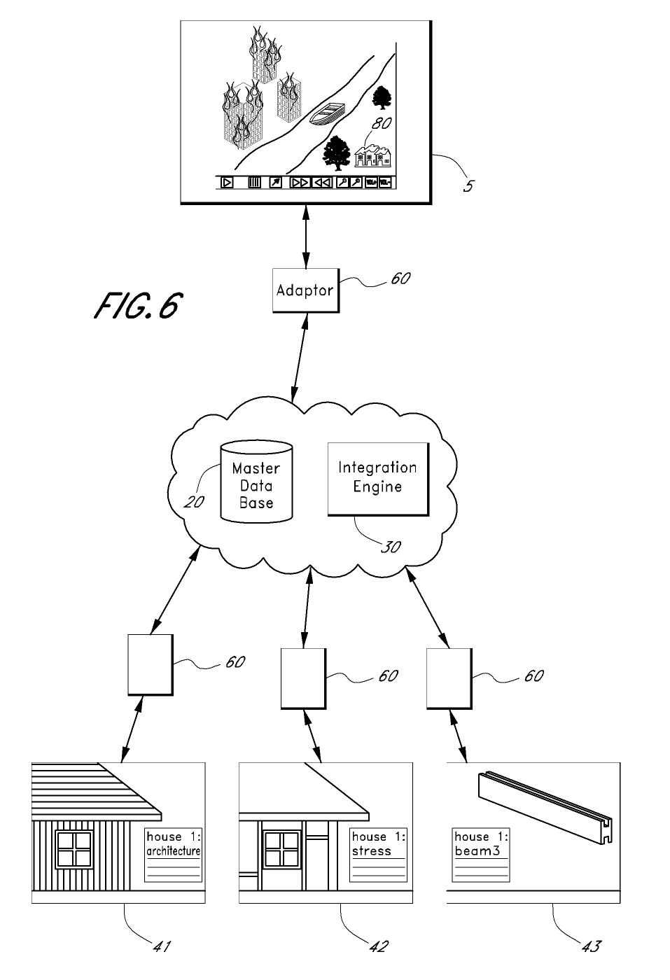

### FIG. 6

FIG. 6 illustrates how an embodiment supports the use of different engineering workflow applications. An architecture workflow application (41) may be used to refine elements of a model into relatively high level objects. For example, such a tool may be used to define the objects that compose a scene (80), as illustrated in FIG. 6. Architecture workflow applications (41) are also particularly useful for manipulating external or organic properties such as the color, height, and size of objects in a design. They are also useful for establishing connections and relationships between high-level objects, such as the relationship between HVAC systems and structural objects or the relationship between a roof and the interior which it covers. Once high-level objects and their relationships are designed, it is common for designers to use other workflow applications to further design the high-level elements. For example, a structural engineering workflow application (42) may be used to analyze the stresses and loads in a wall, and the designer may use it to manipulate objects internal to that wall or subcomponents of the wall. An example of a third engineering workflow application (43) is a workflow application that is highly specific to a particular type of material or a particular task, allowing for detailed and specialized design of an object's properties. Other possible uses of engineering workflow applications are to specify, design, and manipulate the basic objects that are composed into assemblies and ultimately into the high-level objects.

An embodiment thus allows some properties of an object to be designed and manipulated in one workflow application while other properties, including perhaps the objects from which the first object is composed, are designed and manipulated in other workflow applications. Design decisions that could not be made in one type of engineering workflow application (for example, an architecture workflow application (41)) can be made in another. Because the design decision is integrated back into the master database (20) and because the master database (20), adapters (60), and integration engine (30) cooperate according to the configuration of the embodiment to apply business rules, the architecture workflow application (41) will reflect the design decisions made in the other workflow application to the extent that it is capable. As with modeling workflow applications, an engineering workflow application can manipulate and modify objects without losing previously made design decisions, even if those design decisions could not have been made by the engineering workflow application and there is no native capability to represent that design decision. Similarly, design decisions made in any workflow application, including modeling workflow applications, are reflected to the extent possible in the engineering workflow applications because the engineering workflow applications will obtain data from the master-database (20) that has been modified or created according to the application of business and aggregation rules to the latest updates from each of the workflow applications.

The illustrated workflow applications are only examples of the workflow applications that may be used in conjunction with various embodiments of the present inventions. Many other types of engineering and other workflow applications are used in design projects. These tools operate at various levels of granularity and allow designers to manipulate a broad spectrum of objects from which a design is composed. In preferred embodiments, each workflow application communicates with the master database (20) and the integration engine (30) via an adapter (60). In some preferred embodiments, an adapter (60) facilitates use of alternative workflow applications that operate at similar levels of abstraction or manipulate similar properties of similar categories of objects. For example, an embodiment including appropriately configured adapters and business logic allows objects and properties established with Autodesk AutoCAD™ to be manipulated with Parametric Technology Pro/ENGINEER™. Some embodiments generalize the functionality described above, wherein the complete design is accessible in any workflow application to the extent that it is appropriate given the capabilities of the workflow application and any associated adapter (60). Although the workflow application might not support making particular design decisions or displaying particular aspects of the design, the information available to the workflow application reflects all of the design decisions made up to that point. Any changes made using that workflow application will be propagated throughout the master database (20) so that they are similarly available to other workflow applications (assuming that the changes are allowed given the business rules, including the permissioning rules). Just as a user of the workflow application is alerted if design decisions made in other applications have resulted in changes that the user should review, the actions of the user may result in similar alerts being directed at other users and workflow applications.

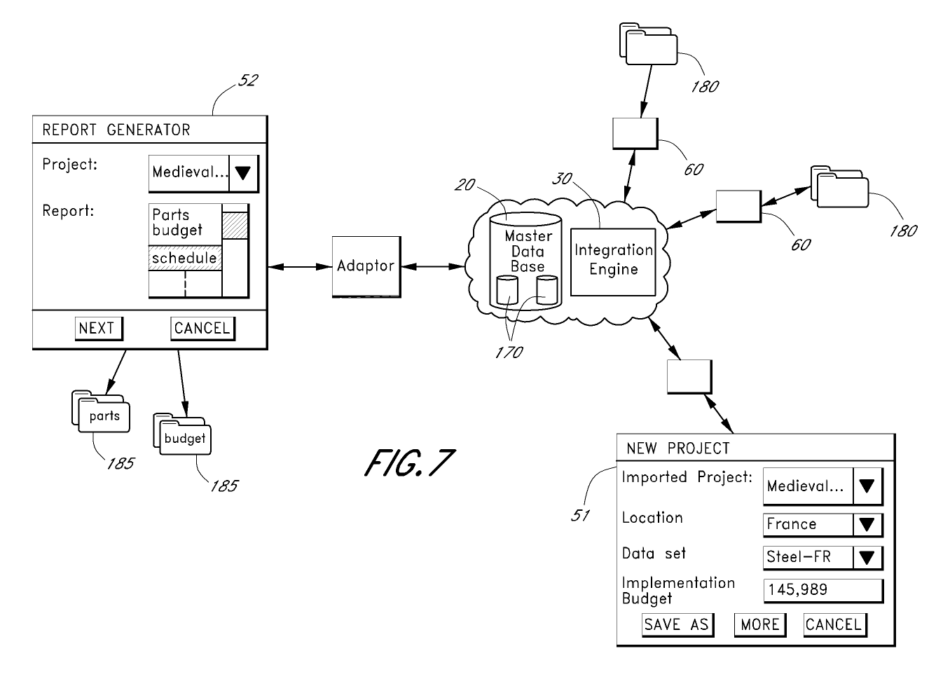

### FIG. 7

FIG. 7 depicts the operation of an embodiment in which third party data or other information in documents (180), information from other design projects (170), and management workflow applications (51 and 52) are included in the design project. Embodiments need not include all of these features and may include additional features. Documents (180) are integrated with the integration engine (30) and master database (20) via adapters (60). Embodiments of these adapters (60) need not interact with the applications or systems used to create the documents (180). This makes these adapters (60) particularly well suited to integrating parts lists, catalog data, and other information which may be generated by systems to which the design project has no direct access. For example, implementation or construction information management systems may be integrated into an embodiment, but in other situations data about a construction or implementation project such as money spent and the degree of construction complete might be available only in document format. However available, information about the construction project is useful in allowing reports such as spend versus budget and percentage completion and in enabling previously described animations.

A master database (20), such as the one illustrated in FIG. 7, may include information about earlier design projects (170). This may include information similar to that stored about the current project, including metadata such as the costs, schedules, and configurations used during the design project. It may also include information about the implementation project (or planned implementation project) to deliver the actual implementation. Such information is of interest to management workflow applications such as reporting and estimating tools, which may use it, for example, to generate reports that help managers assess the value of various design methodologies or workflow applications, the costs of different design projects, and the accuracy of implementation estimates.

The information about earlier design projects (170) is also useful to the designers of the current project, because in the illustrated embodiment and other preferred embodiments those designers can access and reuse design elements from earlier design projects. For example, the design project illustrated in FIGS. 2-6 includes a boat in a river. An earlier project may also have included a boat, perhaps for an actual implementation of an exhibit booth at a sporting-goods conference. The illustrated embodiment allows designers of the current project to access that earlier boat design, including some or all of the simple data reflecting the design decisions made specifically about the boat as well as some or all of the derived data that may have been established based on the business rules associated with the project and design decisions made about other elements of the earlier design. The designers can then import the boat into the current project, leaving the original data about the earlier project unmodified. In some embodiments, details about the reuse itself may be recorded—this is just an example of the metadata that may be recorded and made available to workflow applications.

Rather than design the boat from basic objects, the designers may now reuse and modify the assemblies of objects from which the earlier boat was composed, ensuring that they are in accord with the requirements and restrictions of the current project. This may mean that some or all of the basic objects have to come from different parts lists than in the original project. Reasons for this include current client preferences, changes regarding the original supplier or the market, or because regulatory or design requirements dictate a different set of basic objects be used. Some embodiments may implement a change in parts list by allowing users to specify that data should be sourced from one document (180) and not another. Other embodiments may implement changes in a more automated fashion, taking advantage of information about the design, about the elements of the design, the business rules, and document management information.

When a parts list changes, designers may have to account for differences in the objects on the parts lists and might have to design or source objects that are part of the design but are no longer mapped to actual objects on the parts lists. In preferred implementations the information about the basic objects and actual objects is in a format, such as MasterFormat™, such that objects with the same fundamental properties are coded in a standard fashion. Adapters (60) and workflow applications may be configured to highlight instances where an object in the original design has no sufficiently identical analog from the current parts list and may make use of such a standard coding format in so identifying those instances. Such embodiments enable designers to focus their attention on making modifications enabling reuse the boat design. Preferably, embodiments can also be configured to flag all of the effects of using alternative parts lists, including those impacts that might typically be relatively insignificant because the component in question is standard.

Also shown in FIG. 7 is a project configuration screen from an example project management workflow application (51) which illustrates how some of the features discussed above may be made accessible to a user. In this example, an entire pre-existing project called “medieval fort” and modeling a structure evocative of a medieval fortress is being reused. In this embodiment, the new project is being configured for implementation in France, and based on that information the system (in some embodiments through the coordinated actions of the integration engine (30), adapters (60), and the master database (20)) has made a number of relevant datasets available to the user of the management workflow application, from which the user has selected to use the “Steel-FR” dataset, including information from a French supplier with a specialty in steel materials. Some embodiments may use metadata associated with the datasets and the original design to further narrow the list of appropriate datasets to those including information about the actual objects that will be necessary to implement the design.

The project management workflow application (51) also allows a user to enter a value representing the implementation budget for the new project. Not illustrated are other workflow applications which a user might use to review the estimated and actual costs associated with previous projects, perhaps including previous reuse of the “medieval fort” project, previous reuse of similar projects, and other design projects for implementations in France. This client budget value is maintained in the master database (20) and, as with all other data, it is preferably associated with rules and logic about when it can be updated and by which users or workflow applications. The system may track changes to this and other values through business rules in the integration engine (30), adapters (60), workflow applications, or other means. Such tracking allows changes to be reported on and displayed in appropriate workflow applications, including the animated master-model workflow application (5) of preferred embodiments. In some embodiments, workflow applications that provide budgeting and estimating capabilities can use this data, along with the data about the cost of acquiring basic objects, the cost of assembling composite elements, the cost of complying with regulations, and other implementation costs, to compare the estimated cost of implementing the current design to the client's budget.

The example project management workflow application (51) allows for the information entered to be saved under a user-entered project name. Depending on the amount and type of information in the original “medieval fort” design project, in preferred embodiments the designers may merely need to review the new project to see if the business rules and basic objects associated with the new location and new datasets require any further modifications to the project. If they do, if the earlier project is meant to be just a starting point for a design with different requirements, or if the earlier project was only partially designed, then the designers may use the workflow applications as discussed above to complete the design of the new project.

FIG. 7 also illustrates another example workflow application, a report management workflow application (52). Workflow applications may have their own native reporting and file generation capabilities. In some embodiments, adapters (60) provide workflow applications with additional functionality and access to additional data such that reports and files can be generated. Nonetheless, some embodiments may include dedicated reporting tools, as exemplified by the report management workflow application (52).

The example report management workflow application (52) allows a user to select a project to be reported upon, although in other embodiments it may create reports based on other sources, such as multiple projects, subsets of a project, subsets of multiple projects, or metadata about the configuration of the embodiment itself The tool also allows the user to select the report type and options specific to that report type. In preferred embodiments the available report types, data sources, and report options depend on the permissioning rules and other business logic maintained by the master database (20) and integration engine (30). In addition to options specific to the selected report, a report management workflow application (52) may present additional options such as file format and pretty-print or display options.

Report generation may be implemented using pre-existing reporting software (such as that provided by purpose built reporting components, included in a master database (20), or native to a workflow application) augmented with adapters (60) and configured to interact with the master database (20) and integration engine (30). Reporting workflow applications similar to the illustrated report management workflow application (52) may present extensive options and allow for a wide variety of outputs. Preferred embodiments include report management workflow applications configured to output bills of materials for objects in the design, MasterFormat™ parts lists for objects in the design, implementation schedules, implementation budgets, manufacturing or production specifications for the designed components, and assembly instructions for assemblies comprising the design. For example, if an element of the design is a rockwork object that when implemented will resemble a rock or stone feature with particular characteristics, then reporting workflow applications in a preferred embodiment can generate: a specification for the bar to be used in the rockwork; machine instructions for the machine that will bend and cut the bars; machine instructions that will cause a machine to label each bar; assembly instructions for assembling the bars to create a frame; assembly instructions for assembling the frames to produce the cage; specifications, quantities, and application instructions for the material to be used to cover the cage to create the designed rockwork appearance; detailed production, procurement, and assembly schedules for all of the above; and detailed costing for all of the above. To summarize, preferred embodiments provide all necessary data and metadata to reporting workflow applications so that those applications can generate the reports that make a design manufacturable.

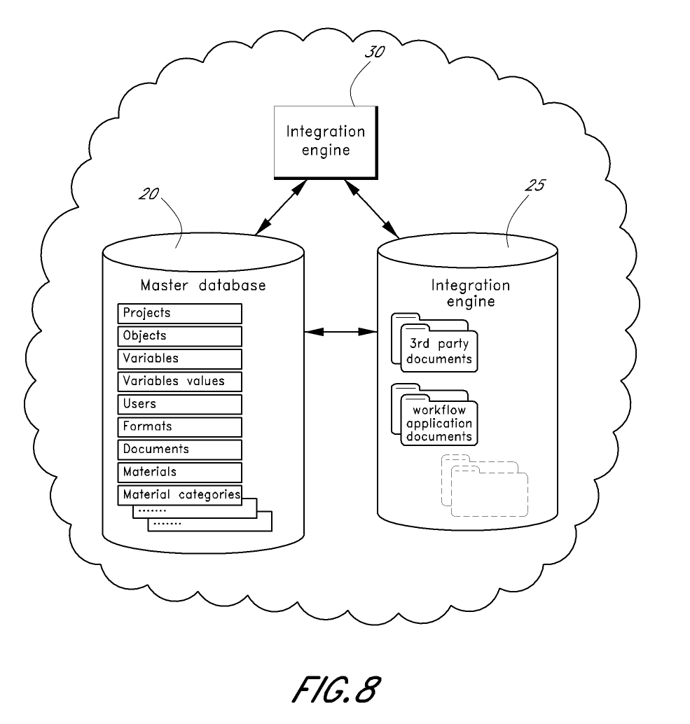

### FIG. 8

FIG. 8 shows a representation of an example master database (20), which may be implemented by a relational database system such as Microsoft SQL Server™ and a document management system (25) such as the SolidWorks PDM Vault™. In the illustrated embodiment, there is a table for each project, and that table contains basic metadata about that project. A project may be associated with different documents, and a given document may be associated with more than one project. The relational database may contain information about a document, but the document itself may be maintained in the document management system (25). In other embodiments, the documents may reside on a file system or other storage device and not be under the purview of a dedicated document management system. In further embodiments, the data within the documents is represented in the master database system (20) even if the documents themselves are not directly managed by the by the master database (20). Documents are typically created by workflow applications such as those discussed above, as well as general purpose applications such as Microsoft Office™, Open Office™, or Google Documents™ applications. Documents may be of any format, including the formats associated with the workflow applications, PDF, PostScript™, and image and animation formats.

As discussed above, designers create and manipulate objects during the course of the design project. In the illustrated embodiment of the master database (20), the master database associates an object with at most one project. The reuse of objects described earlier is implemented by creating a new object that copies the original one. In other implementations, other methods of reuse can be implemented, such as associating a given object with multiple projects or using copy tables that point to the original object and contain only the data that differs.

FIG. 8 shows that in a preferred embodiment, the master database (20) represents variables as entities independent of objects. This allows for variables to be associated with entities other than objects, and for the system to establish and maintain a standard set of variables (for example, those associated with different reports, or those necessary to enable particular workflow applications such as the preferred animated master-model workflow application (5)). Variables need not correspond to properties manipulated with workflow applications. They may, for example, represent derived properties or properties used to implement the business logic of the system. The values of the data in these tables may be maintained by adapters (60), an integration engine (30), or by one or more workflow applications implementing the business logic of the system.

Some instances of the master database (20) include additional tables to maintain information about other aspects of design projects and to maintain metadata. For example, FIG. 8 shows a set of tables relating to materials. These tables store information corresponding to the basic objects discussed above. One of an object's variables may point to the objects from which it is assembled, the materials from which it composed, or to information necessary for the production of that object. The illustrated materials tables represent actual objects and support parts list substitution, described above. They also support management and reporting workflow applications that allow suitably permissioned users to query and manipulate the materials available to a design or elements of that design.

Many tables present in preferred embodiments are not illustrated, including tables necessary to implement permissioning and to support much of the functionality discussed above. However, given this disclosure, one of skill can readily design appropriate tables and relational rules to implement the functionality of the described embodiments as well as other functionality that would be readily useful to practitioners using such embodiments.

In addition to the document-project association, there may also be a document-object association. A document may be associated with multiple objects, a document may be associated with a single object, multiple documents may be associated with an object, or an object may be independent of any document. An object may be independent of any document because, for example, it was once associated with a document but that document no longer exists, it was created by the system itself, or the master database (20) stores only objects and does not track or manage documents.

While there are multiple ways of ensuring the integrity of the objects and documents, in the illustrated implementation when a workflow application is being used to edit an object any document implementing that object is checked out of the document management system (25) and marked as locked in the database (20). The objects and variable values associated with that object are also marked as locked. Other workflow applications may be able to view that object, but in preferred embodiments the adapters (60) for those applications will ensure that the workflow applications do not change the locked data. If adapters (60) do try to update locked data in the master database (20), then the integration engine (30) or other entities responsible for enforcing the business logic should prevent it. Preferred embodiments also inform users that an object is locked and that properties of that object may be changing. This may be done in the context of a workflow application, perhaps with the aid of an adapter (60), or by a dedicated reporting workflow application (190). There is a rich body of cooperative development systems and workflow management systems which can be applied in various embodiments. Some embodiments allow highly granular locking so that, for example, variables representing external properties of an object (such as color) can be manipulated in one workflow application even as variables representing internal properties (such as the non-visible structural objects from which it is assembled) or even other external properties (such as dimensions) are manipulated in another workflow application. In some embodiments, users manipulating or viewing objects related to a locked object are alerted to the locked status of that object and made aware that someone may be making or modifying design decisions that could impact the objects they are viewing or manipulating.

While FIG. 8 illustrates a preferred embodiment of a master database (20) that uses a relational database system operating in conjunction with a document management system (25) and an integration engine (30) other implementations may use relational databases, flat file systems, object-orientated databases, integration engines (30), or document management systems (25) alone. Practitioners will be able to implement embodiments using these and other systems.

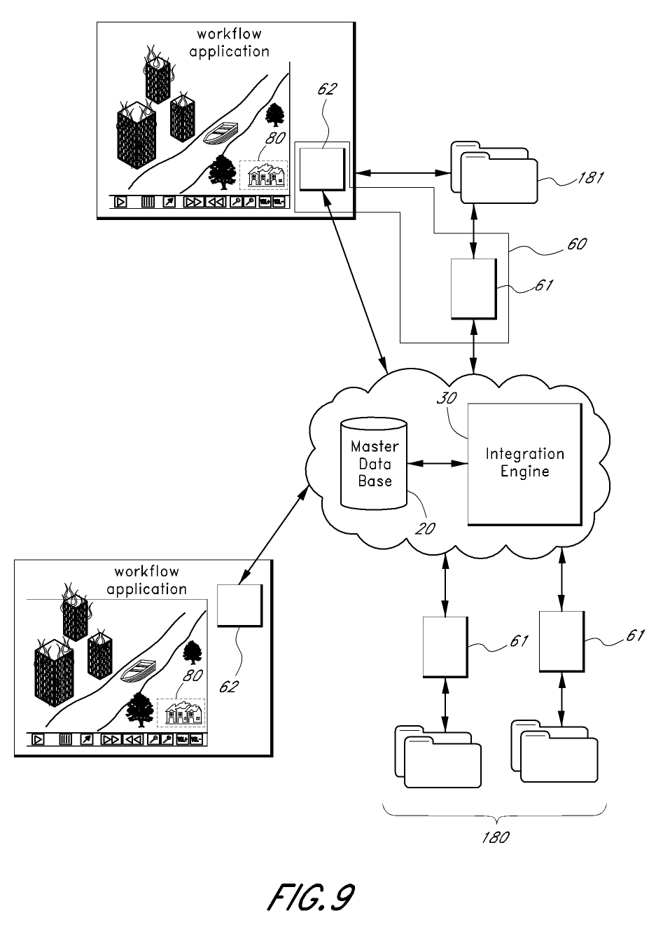

### FIG. 9

Generally, adapters (60) provide functionality that enables the various systems and data sources relevant to a design project to interact with the design data. Adapters (60) need not provide the same functionality to all workflow applications or even provide similar functionality in similar ways.

Adapters (60) preferably make extensive use of pre-existing integration between a target workflow application and the master database (20) or integration engine (30). Any necessary functionality not provided by pre-existing integration may be implemented using a standard or supported extensibility service for the target system. For example, many SolidWorks™ products support an API that allows extensibility. Other products, such as Microsoft Office™ applications, are extensible through the use of macros and scripting languages such as Visual Basic™. Autodesk 3DS Max™ also provides an extension mechanism.

Adapters, like other disclosed systems including the master database (20), integration engine (30), and workflow applications, are preferably implemented as executable code modules that are stored on a computer-readable storage medium such as hard disk storage or solid state memory. FIG. 9 shows that an adapter (60) may be implemented by two separate components: a connector (61) and a plug-in (62). Connectors (61) are preferably non-intrusive, meaning the workflow application with which the connector (61) communicates operates as it normally would and is not modified in any way to work with the communicator (61). Plug-ins (62) preferably modify the workflow application to which they are attached, providing functionality not available natively in the workflow application.

In some embodiments, adapters (60) operate on the documents produced or consumed by a workflow application. Such adapters (60) are typically comprised of a connector (61). Such adapters (60) need not interact with the applications or systems used to create the document and are thus preferred for operating on third-party data such as parts lists, catalog data, and other information which may be generated by systems to which the design project has no direct access. Embodiments of these adapters need not have a plug-in (62). Indeed, if there is either no application to host a plug-in (62) or if access to that application is restricted such that implementing or deploying a plug-in (62) would be difficult, an adapter (60) comprising a connector (61) is the preferred embodiment.

An adapter (60) may incorporate an awareness of a particular document's schema, or it may access an external reference describing the schema and incorporate logic as to how to read that reference. Such a reference is, in preferred embodiments, stored in the master database (20). When an adapter (60) is invoked to generate or update a document, it will, in preferred embodiments, also be given data to process. It may be provided with an object or set of objects, or it may be provided with information sufficient to obtain the target data. In preferred embodiments, the adapter (60) will use the business rules of the project or the conventions of the particular embodiment to identify the variables and other data elements associated with its target data. The business rules of the system will have ensured that each piece of data in the master database (20) is appropriately tagged and the adapter will have access to information describing the correspondence between a document's schema and the tags in the master database (20). An adapter (60) may use these tags or other indicia, along with the business rules and other data in the master database (20) to read and write data in a semantically appropriate fashion.

An example of a simple adapter (60) comprising a connector (61) is one that that generates a list of all the actual parts used by a project or by an object in that project —in some embodiments it need only traverse the project's data and identify the quantity of every basic object used by the system and every object that is to be manufactured. A more sophisticated adapter (60) may comprise a connector (61) that incorporates a substantial amount of business logic and generates a complicated document for use by an engineering workflow application or a modeling workflow application. In some embodiments, an adapter (60) may be invoked to generate a document that includes information which can not be interpreted natively by the target workflow application. Some of these embodiments include adapters (60) comprising plug-ins (62) that extend the functionality of target workflow applications, allowing them to interpret the information for display and modification as described below.

Adapters (60) may also be comprised of connectors (61) which parse documents created using workflow applications (181) or otherwise made available to the design project (180). In preferred embodiments, the adapters (60) update the master database (20) with information from these documents. Various embodiments may invoke adapters (60) operating in this mode in a variety of ways. When the adapter (60) is invoked, it preferably parses the document according to a schema, as described above. In some embodiments, it will know where to store the data read from the document based on information provided at invocation. In other embodiments, this information may be provided by the master database (20) or the integration engine (30), based on, for example, business rules and the object-document table illustrated in FIG. 8. Processing information may also be embedded in the document name or in the document's data. For example, information may be included in a Microsoft Word™ comment or a specially designated AutoCAD™ object.

In preferred embodiments, when an adapter (60) updates the master database (20), it does so through the integration engine (30), which, as described, ensures that appropriate fields and tables are updated or created. In other embodiments, the adapter (60) itself may be responsible for updating the master database (20). The updating process preferably includes updating metadata such as “last-updated” fields and updating or creating any fields or tables necessary for the various adapters (60) to appropriately parse the updated information and to recognize, through application of the business rules, the design decisions made in the workflow application or document targeted by the updating adapter (60).

Connectors (61) may be implemented as software modules closely associated with the master database (20) and running on the same computing system as the master database (20), integration engine (30), or document management system (25). In other embodiments, connectors (61) need only have connectivity to the master database (20), integration engine (30), or document management system (25).

A plug-in (62) is an example of an adapter (60) component which enables a workflow application to provide functionality not available natively in the application. For example, in some of the embodiments discussed above, such as those illustrated in the figures, a master-model workflow application (5) allows a user to view and manipulate both organic and regular models despite a typical master-model workflow application being natively designed to specialize in one type of model or the other. Other examples of a workflow application presenting information not originally entered using that application are discussed above, including the ability of an animated master-model workflow application to present and animate detailed time and cost data about the design and about the implementation of that design. In preferred embodiments, capabilities that are not provided natively by the application are provided by plug-ins (62).

A plug-in (62) need not significantly modify the user experience of a workflow application. In some embodiments a plug-in is largely invisible to a user and performs the same role as a connector (61): relaying information from the workflow application to a master database (20) and providing the workflow application with updated information about the state of the design as it is modified by activities outside of the target workflow application.

A plug-in (62) may be a software module written using a scripting language or by programming to an API supported by the target workflow application. A plug-in (62) may have more than one component, such that at least one component extends the target workflow application by providing user interface elements or otherwise interacting with the workflow application. Other plug-in (62) components may be external to the workflow application and may run on different hardware than the workflow application. Such a remote component of the plug-in (62) might contain business logic and be responsible for querying or updating the master database (20) according to the business rules in the integration engine (30). Because of the high degree of interaction between the native component of the plug-in and the target workflow application and the high degree of interaction between the remote component and the master database (20) and integration engine (30), each component preferably has at least a high speed connection to its counterpart. The two components may deliver adequate performance while communicating with each other over a slower connection.

An adapter (60) incorporating a plug-in (62), even a plug-in (62) that does not extend the target application's user interface or capabilities, can still be very valuable. For example, many workflow applications typically read a source file when a user opens information in the workflow application and write to the file when the user wishes to save any work done. While the user uses the workflow application, the workflow application typically does not update the documents (181) that a connector (61) targets. On the other hand, a plug-in (62) that takes advantage of interfaces exposed by a target workflow application (such as API's or known behavior) can often be configured to operate independently of the opening and saving of any particular file. An adapter (60) including a plug-in (62) may therefore be able to update a target workflow application with information about changes to the design in something approaching real-time (subject to the particulars of the target workflow application, the business rules that invoke the adapter (60), and the computing and networking systems of the specific embodiment). Such an adapter is similarly capable of updating the master-database (20) with information about the work being done in the target workflow application when that work is done instead of when that work is written to a file.

Methods of invoking an adapter (60) vary. Some adapters (60), such as those that process third party documents (180) that are outside the control of the design team, may be invoked directly or through a management workflow application. In some embodiments, adapters may be invoked by the integration engine (30) or other business rules of the system such that they run whenever a file is checked in or checked out, as appropriate. In other embodiments, the system may regularly monitor certain storage locations, automatically running adapters (60) when changes to the documents in those locations are detected. Similarly, some embodiments may regularly run adapters (60) at regular time intervals or when data in the master database (20) is updated, ensuring synchronization among the various workflow applications and documents. Adapters (60) may also be invoked by a user of the targeted workflow application.

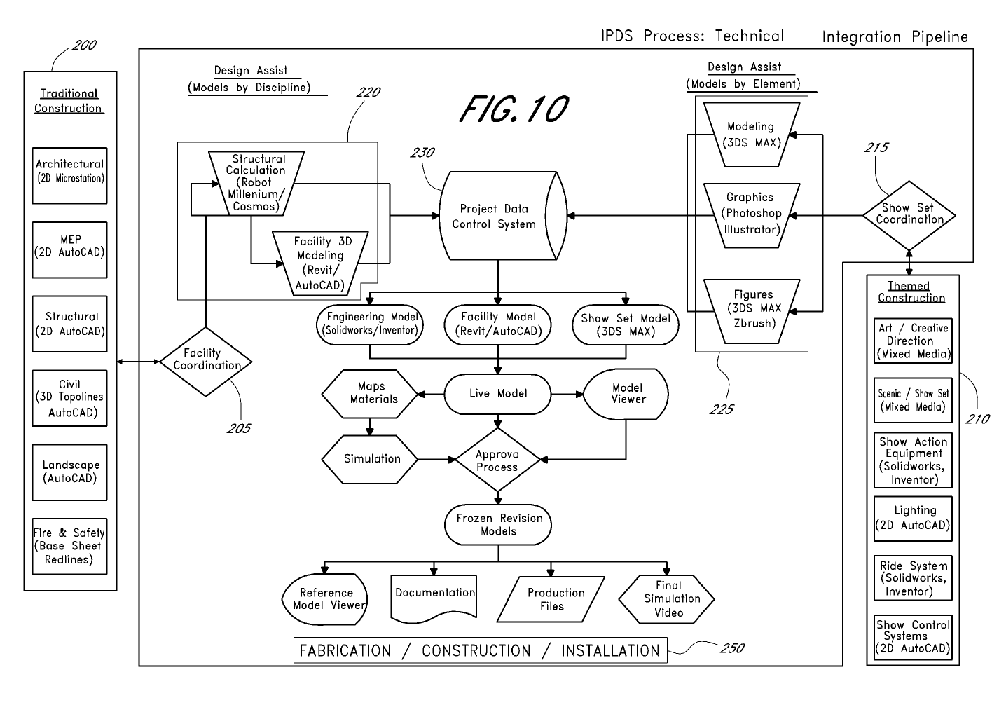

### FIG. 10

Another embodiment is shown in FIG. 10. Block 200 shows examples of traditional engineering or design tasks including architectural design, mechanical/electrical/plumbing design, structural engineering, civil engineering, landscaping, and fire & safety planning. It also lists some of the workflow applications that might be used or the name traditionally given to the output of that design task (e.g., base sheet redlines). Block 210 shows examples of engineering or design tasks associated with interactive or themed construction, including setting an overall create direction, designing a background set, designing action, modeling lighting, creating ride systems, and establishing control systems. It also lists some of the workflow applications that might be used to perform these tasks or the type of documents that might be produced (e.g., mixed media). Block 250 represents the implementation tasks of fabricating, constructing, installing, or otherwise realizing the product being designed.

In the particular embodiment illustrated in FIG. 10, the tasks in 200 and 210 are not done by the design team and what is available to the design team are read-only documents representing the outputs of those tasks. Diamonds 205 and 215 represent coordination between the design team and those responsible for the tasks in 200 and 210. Such coordination may be effected manually or electronically and may be supported by automated systems. Although not illustrated in the figure, the information from the various tasks in blocks 200 and 210 can be stored in the live model. In other embodiments the files associated with those tasks may also be managed by document management capabilities of the embodiment, explicitly associating document check-in or data storage with the coordination represented by 205 and 215. It may also be loaded, manually or automatically, into the workflow applications represented by the trapezoids in 220 and 225.

The workflow applications in 220 include a structural engineering or calculation workflow application such as Robot Millennium™ or SolidWorks COSMOS™ and a multi-dimensional facility modeling workflow application or regular-model workflow application such as Autodesk Revit™. Designers use these tools to manipulate the objects designed during the performance of the tasks in 200. Similarly, designers use the organic modeling, graphics, and figure drawing workflow applications in 225 to manipulate the information created in 210. The design decisions and other work done using workflow applications in 220 and 225 are maintained in a project data control system (230). The project data control system enables the workflow applications in 220 and 225 to better share information among themselves, but it also allows data more traditionally manipulated by the workflow applications in 220 to be available to workflow applications in 225, and vice-versa. This may be done on a parametric basis such that each of the workflow applications has a copy of the design and is entitled to make certain changes, with the project data control system (230) containing the necessary business logic to integrate those changes and communicate them to the other workflow applications. The project data control system (230) also maintains historical representations of each element in the design and any associated metadata such as costs, assembly, and sourcing information about the elements or the design as a whole.

From the project data control system (230), data about the design is available to different modeling tools that are suited for particular purposes, such as the engineering, facility, and show-set model workflow applications shown. These model workflow applications are used in some embodiments to further refine and modify the design, and the results are made available in a consolidated live model. Whereas the project data control system (230) might contain data in a variety of formats and include information necessary to manage version control, implement document management, and otherwise support an ongoing collaborative design project, the live model is an accumulation or aggregation of the design work that has taken place. The live model can be viewed in a model viewer, which implements much of the viewing functionality of the master-model workflow application described in other embodiments. If associated with information in the maps materials hexagon, the live model can also be experienced in a simulation. The maps material includes the additional data necessary to render an experiential simulation or animation that changes as time passes or some other variable (such as cost or users) varies.

After viewing the design in the model viewer and in simulation, an approval process ensues. Approval could be automated. For example, it might be based on whether the simulation meets certain criteria. It may also be a manual process, whereby users express satisfaction, or not, with the design as viewed and simulated. Because the live model is fully dimensioned and complete, the simulation and model are not simply superficial renderings of the design, but they allow users or viewers to explore the design at any level and to reach an informed approval or disapproval.

If approval is granted, then the model may be locked. Additional design work may be proceeding or may take place in the future, but the approved design is secured from being affected by that work. That locked model is a source of inputs to the implementation tasks in block 250. The files and documents necessary to make the design manufacturable can be generated from this locked live model, as described when discussing other embodiments above. Also, reference model views and final simulation videos can be created, which are tailored for use by implementers and provide easy access to the data and perspectives they will find useful.

### SUMMARY

Although specific embodiments have been disclosed, other embodiments that are apparent to those of ordinary skill in the art, including embodiments which do not provide all of the benefits and features set forth herein, are also within the scope of this disclosure. The foregoing description of preferred implementations has been presented by way of example only, and should not be read in a limiting sense. Accordingly, the scope of protection is defined only by reference to the appended claims. As used in these claims, “construction project” includes, but is not limited to, any project involving the creation of artifacts. For example, building construction, landscaping, exhibit creation, campus design, and representations of such artifacts in virtual environments are all “construction projects”.

All of the systems described above may include one or more general purpose computers or processors and/or may include one or more special purpose computers or processors. All of the processes described above may be embodied in, and fully automated via, software code modules executed by one or more general purpose computers or processors, or alternatively, by specialized computer hardware. The code modules may be stored in any type of computer-readable medium or computer storage device. The various computer hardware resources (physical computers, processors, storage devices, etc.) used to run the disclosed software components, and to implement the associated databases, collectively form and operate as a computerized modeling machine or system. The various processing nodes of the computerized modeling machine or system may communicate over one or more computer networks, and may, but need not, be co-located.

What is claimed is:

1. A computer implemented system operative to store construction project information originating from multiple sources and to apply rules about the construction project so that it can provide integrated and dimensioned construction project information, comprising:
physical computer storage that stores:
a first computer representation of information about a design of a construction project;
a second computer representation of objects and assemblies of objects included in the design;
a third computer representation of information about basic objects, such that said information about basic objects is sufficient to source or manufacture those basic objects;
a fourth computer representation of information relating the basic objects to the objects and assemblies of objects;
a computer representation of rules for aggregating the information about the basic objects, objects, and object assemblies; and
a fifth computer representation of information about the implementation of the design, and
a computer system comprising computer hardware and software configured to apply the rules to generate or update a sixth computer representation of derived information about the design and the construction project based on the first, second, third, fourth, and fifth computer representations.

2. The system of claim 1, further comprising a write-adapter including computer software configured to output information in the sixth computer representation, said write-adapter comprising computer software and hardware.

3. The system of claim 1, further comprising a read-adapter comprising computer software and hardware configured to communicate with a source of construction project information and update the first, second, third, fourth, fifth, or rules computer representations based on information from the source.

4. The system of claim 1, wherein the computer system configured to apply the rules is further configured to apply those rules whenever the information in the computer representations is modified.

5. The system of claim 1, wherein:
the physical computer storage also stores:
a computer representation of cost information about the basic objects and
a computer representation of cost information about implementation; and
the computer representation of rules also includes computer representations of rules for aggregating the cost information.

6. The system of claim 1, wherein:
the physical computer storage also stores a computer representation of information about the time necessary to procure the basic objects, assemble the objects and object assemblies, and otherwise complete implementation; and
the computer representation of the rules also includes computer representations of rules for aggregating the time information.

7. The system of claim 1, wherein the representation of the rules also includes computer representations of rules which depend on information independent of the construction project, such as regulatory, environmental, and weather information.

8. The system of claim 7, wherein the physical computer storage also stores a computer representation of information independent of the design and the construction project.

9. The system of claim 8, where the independent information includes regulatory information.

10. The system of claim 8, where the independent information includes environmental information.

11. The system of claim 8, where the independent information includes weather information.

12. The system of claim 8, where the independent information includes climate information.

13. The system of claim 1, wherein:
the physical computer storage also stores a computer representation of standard stock models for the basic objects and a computer representation indicating which standard stock models a particular project is using; and
the computer representation of the rules includes computer representations of rules which depend on information in the computer representations of standard stock models.

14. The system of claim 2, wherein the physical computer storage also stores a computer representation of information about computer file formats.

15. The system of claim 14, wherein the write-adapter is further configured to output information in a computer representation formatted according to the information stored in the computer representation of claim 14.

16. The system of claim 14, wherein the computer representation of information about computer file formats includes information about computer file formats of an animation system.

17. A computer implemented process comprising:
storing a first computer representation of a design of a construction project;
storing a second computer representation of objects and assemblies of objects included in the design of the construction project;
storing a third computer representation of information about basic objects, such that said information about basic objects is sufficient to source or manufacture those basic objects;
storing a fourth computer representation of information relating the basic objects to the objects and assemblies of objects;
storing a computer representation of rules for aggregating the information about the basic objects, objects, and object assemblies;
storing a fifth computer representation of information about the implementation of the construction project; and
applying the aggregation rules to generate or update a sixth computer representation of derived information about the project based on the first, second, third, fourth, and fifth computer representations;
wherein the process is performed by a computerized system that comprises computer hardware and software modules configured to perform the process;
whereby the process stores construction project information from diverse sources and applies rules about the construction project to consistently update the information and enrich it beyond what any one of the sources could do alone.

18. The process of claim 17, further including outputting a computer representation of information derived by the application of the aggregation rules.

19. The process of claim 17, further including updating the information in the first, second, third, fourth, fifth, or rules computer representations.

20. The process of claim 17, wherein the aggregation rules are applied whenever the information in the computer representations is modified.

21. The process of claim 17, further including storing a computer representation of cost information about the basic objects and storing a computer representation of cost information about construction; wherein the aggregation rules also include rules for aggregating the cost information.

22. The process of claim 17, further including storing a computer representation of information about the time necessary to procure the basic objects, assemble the objects and object assemblies, and otherwise complete construction; wherein the aggregation rules also include rules for aggregating the time information.

23. The process of claim 17, wherein the rules also include rules which depend on information independent of the construction project, such as regulatory, environmental, and weather information.

24. The process of claim 17, further including storing a computer representation of information independent of the construction project, such as regulatory, environmental, and weather information.

25. The process of claim 17, further including:
storing a computer representation of standard stock models for basic objects and
storing a computer representation indicating which standard stock models a particular project is using,
wherein the rules also include rules which depend on information in the computer representations of standard stock model information and use.

26. The process of claim 18, further including storing a computer representation of information about computer file formats.

27. The process of claim 26, wherein outputting a computer representation includes outputting a computer representation prepared according to the information stored in the computer representation of claim 26.

28. The process of claim 26, wherein the computer representation of information about computer file formats includes information about computer file format of an animation system.
